(19) United States
(12) Patent Application Publication
(10) Pub. No.: US 2010/0065834 A1
(43) Pub. Date: Mar. 18, 2010

(54) INTEGRATED ORGANIC PHOTOVOLTAIC AND LIGHT EMITTING DIODE DEVICE

(75) Inventor: Troy D. Hammond, Pittsburgh, PA (US)

Correspondence Address: FOLEY AND LARDNER LLP;SUITE 500, 3000 K STREET NW, WASHINGTON, DC, 20007, US

(73) Assignee: Plextronics, Inc.

(21) Appl. No.: 12/560,306

(22) Filed: Sep. 15, 2009

Related U.S. Application Data
(60) Provisional application No. 61/097,465, filed on Sep. 16, 2008.

(51) Int. Cl. H01L 51/46; H01L 51/52; H01L 51/48; H01L 51/56

(52) U.S. Cl. 257/40; 438/25; 257/E51.039; 257/E51.029; 257/E51.012; 257/E51.022; 977/734

(57) ABSTRACT

An integrated organic photovoltaic and electroluminescent device includes an organic light emitting diode and an organic photovoltaic. The OLED and the OPV share a common substrate building layer.

### CROSS-REFERENCE TO RELATED APPLICATIONS

This application claims priority to U.S. Provisional Patent Application No. 61/097,465, filed on Sep. 16, 2008, the disclosure of which is hereby incorporated by reference in its entirety.

### BACKGROUND

Organic electroluminescent devices can utilize organic small molecules or polymers that produce light when transferred into their excited state by an external power source. The excited state is created when positive and negative charges flow from opposite electrodes into the electroluminescent materials. Frequently, in multi-layer devices, hole injection and/or hole transport materials between one electrode and the electroluminescent material improve the efficiency of the device. These devices are being designed for use in for example white lighting. With increasing commercial demands, however, better devices are needed which have better materials suited for particular applications and which can be tailored, commercially made, and provide good stability.

Organic photovoltaic (OPV) devices provide advantages and improvements over older silicon devices. See for example Perlin, John “The Silicon Solar Cell Turns 50,” NREL 2004; see also, Dennler et al., “Flexible Conjugated Polymer-Based Plastic Solar Cells: From Basics to Applications,” Proceedings of the IEEE, vol. 93, no. 8, August 2005, 1429-1439. Global climate changes and increases and instability in fuel prices provide an increased need for OPV devices.

U.S. Patent Application Publication No. 2006/0227531 (Iou) describes an OLED display in combination with a photovoltaic cell. U.S. Pat. No. 7,157,851 (Lee et al.) describes a self-charging organic electroluminescent display device. U.S. Pat. No. 6,028,327 (Mizoguchi et al.) describes an organic electroluminescent light-emitting element.

### SUMMARY

Embodiments provided herein include, for example, devices, apparatuses, and methods of making and using the same.

In one aspect, an integrated organic photovoltaic and electroluminescent device is provided comprising an organic light emitting diode (OLED), and an organic photovoltaic (OPV). The OLED and the OPV can share a common substrate building layer.

In one embodiment, the device is a modular chip configured to be coupled to other modular chips.

In one embodiment, the device is configured as a lighting device.

The OLED and the OPV can share a common electrode. The common electrode can be the cathode, or an anode.

In one embodiment, the OLED and the OPV share a common electrode, wherein the device has a lateral dimension less than about two inches.

In one embodiment, the OLED and the OPV share a common cathode, and the common cathode has two reflective surfaces configured to reflect light into the OLED and the OPV, respectively. The common cathode can have two reflective surfaces configured to reflect light into the OLED and the OPV, respectively, and wherein the OPV comprises a distributed Bragg reflector (DBR). The OPV can comprise a waveguide or a resonant cavity configured to reflect light multiple times within the OPV. The waveguide or resonant cavity is optimized for wavelengths that have the highest conversion quantum efficiency for the OPV.

In one embodiment, the OLED comprises a white light emitter. In another embodiment, the OLED comprises a colored light emitting layer.

In one embodiment, the OLED is closer to the substrate building layer than the OPV, and the OPV is stacked on top of the OLED with respect to the substrate building layer. In another embodiment, the OPV is closer to the substrate building layer than the OLED, and wherein the OLED is stacked on top of the OPV with respect to the substrate building layer.

In one embodiment, the device further comprises a reflective surface configured to reflect light passing through the OPV back to the OPV at least once, wherein the reflective surface is also configured to reflect light generated in the OLED.

In one embodiment, the cathode is selected from the group consisting of Ba, Ca, LiF, Al, Ag, and combinations thereof.

In one embodiment, the OPV and the OLED share a common cathode, wherein the cathode comprises Al and has two reflective surfaces configured to reflect light at least once into the OLED and the OPV, respectively.

In one embodiment, the cathode can be between approximately 80 and 200 nm thick.

In one embodiment, the OPV comprises at least one conjugated polymer.

In one embodiment, the OLED comprises at least one small molecule dopant that is either fluorescent or phosphorescent.

In one embodiment, the OPV comprises a fullerene.

In one embodiment, the OPV comprises an optionally substituted polythiophene.

In one embodiment, the device does not comprise and is not part of a display.

In one embodiment, the OLED comprises a light emitting layer between approximately 30 and 150 nm thick.

In one embodiment, the OLED comprises a light emitting layer that is approximately 100 nm thick.

The OPV can have an active layer that is between approximately 70 and 300 nm thick. In one embodiment, the active layer is approximately 180 nm thick.

In one embodiment, the OPV comprises at least one of a first HIL or a first HTL, and wherein the OLED comprises at least one of a second HIL or a second HTL. The first HIL or HTL can be between approximately 30 and 200 nm thick, and the second HIL or HTL can be between approximately 30 and 200 nm thick.

In another aspect, a method for making an integrated OPV and electroluminescent device is provided. The method includes providing a substrate building layer optionally comprising a first transparent conductor, providing at least one of a first HIL or a first HTL, providing a light emitting layer, providing a cathode, providing an OPV active layer, providing at least one of a second HIL or a second HTL, providing a second transparent conductor, providing an encapsulant, combining the substrate building layer, the first transparent conductor, the at least one of the first HIL or the first HTL, the light emitting layer, the cathode, the OPV active layer, the second HIL and/or HTL, the second transparent conductor, and the encapsulant, wherein the device is adapted to be a lighting device.

The method can further comprise layering on the substrate building layer in the order: the first HIL and/or HTL; the OPV active layer; the cathode; the light emitting layer; the second HIL and/or HTL; the second transparent conductor; and the encapsulant; wherein the substrate building layer comprises the first transparent conductor.

In one embodiment, the OPV active layer comprises at least one of a fullerene, a copolymer comprising a DTP repeat unit, an aryl-substituted conjugated polymers, or a substituted polythiophene.

In another aspect, an integrated organic photovoltaic and electroluminescent device is provided. The device comprises an OLED comprising, a transparent electrode layer, at least one of a first HIL or a first HTL layer comprising a regioregular polythiophene, and a white light emitter. The device further comprises an OPV comprising an OPV active layer, at least one of a second HIL or a second HTL layer comprising a regioregular polythiophene, and a second transparent electrode layer, and a cathode, wherein the OLED and the OPV share a single substrate building layer and the cathode, and wherein the device is adapted to be a lighting device.

In one embodiment, the OLED is stacked on top of the OPV. In another embodiment, the OPV is stacked on top of the OLED.

The OLED or the OPV can further comprise an interlayer comprising one of Ba, Ca, LiF, or combinations thereof.

In another aspect, a lighting system is provided comprising a plurality of lighting devices, each lighting device comprising an OLED and an OPV, wherein the OLED and the OPV share a common substrate building layer.

In one embodiment, the plurality of lighting devices include devices of different colors, and wherein the lighting system is configured to produce white light in a far-field.

In one embodiment, at least some of the plurality of lighting devices are configured to be removably mechanically and electrically coupled to each other.

The system can further comprise a mount, wherein at least some of the plurality of lighting devices are configured to be removably mechanically and electrically coupled to the mount.

In another aspect, an apparatus is provided comprising a plurality of OLED regions, a plurality of OPV regions, and an insulating layer electrically separating the plurality of OLED regions and the plurality of OPV regions, wherein the plurality of OLED regions and the plurality of OPV regions share a common substrate building layer.

In one embodiment, the plurality of OPV regions are configured to be serially connected to produce a useful output voltage for charging a battery. The plurality of OPV regions can be configured to produce a peak voltage of 18-24 V.

In one embodiment, the plurality of OLED regions are configured to be connected in parallel to permit application of a substantially equal voltage and useful current density to the plurality OLED regions. The plurality of OLED regions can be configured to be connected in parallel to permit application of a substantially equal voltage of 4-10 V and useful current density of 20-100 mA/cm² to the plurality of OLED regions.

In one embodiment, at least some of the plurality of OLED regions have different colors, wherein the apparatus is configured such that a far field light is substantially white.

In another aspect, an apparatus is provided comprising an OLED region, an OPV region, a thin film battery disposed between the OLED and OPV, and two insulating layers separating the OLED and the OPV from the thin film battery respectively, wherein the OLED region, the OPV region, and the thin film battery share a common substrate building layer.

In one embodiment, the apparatus further comprises a switch configured to flip the thin film battery from receiving charge from the OPV to delivering charge to the OLED.

In another aspect, an integrated photovoltaic and electroluminescent apparatus is provided including an organic light emitting diode (OLED), and a photovoltaic (PV) device, wherein the OLED and the PV device share a common encapsulation, and wherein the OLED and the PV device are built on separate transparent substrates and are joined together. For example, they can be joined together by lamination or other joining methods known in the art.

In one embodiment, the PV device comprises an organic photovoltaic (OPV) device. In another embodiment, the PV device comprises at least one of a printable thin-film silicon, CIGS, CIS, or CdTe layer.

In one embodiment, the PV device and the OLED can share a common electrode. In another embodiment, the PV device and the OLED are separated by an insulating layer.

One or more embodiments described herein can provide one or more advantages. For example, one possible advantage includes significantly reduced material and manufacturing costs as compared to the cost of two separate devices to provide the same functionality. In addition, for example, a monolithic device can be made.

Another advantage for at least one embodiment is that the lighting can be dimmable to conserve and extend usage hours. In contrast, for example, fluorescent light typically is not dimmable.

In at least some embodiments, the lifetime of the solar component and the lighting component can be similar and comparable to the life of a rechargeable battery. A fully integrated product can be made, for example, where each component (e.g., light, solar cell, and battery) has a similar durability or lifetime after which the product is disposed.

Another advantage for at least some embodiments includes that the consumer can carry a single device that provides both energy capture, such as solar energy, and lighting instead of requiring two separate devices.

### BRIEF DESCRIPTION OF THE FIGURES

FIG. 1 illustrates an integrated OPV and OLED.

FIG. 2 illustrates another embodiment of an integrated OPV and OLED.

FIG. 3 illustrates another embodiment of an integrated OPV and OLED.

FIG. 4 illustrates another embodiment of an integrated OPV and OLED.

FIG. 5 illustrates another embodiment of an integrated OPV and OLED including an insulating layer that separates cathodes of the OPV and the OLED.

FIG. 6 illustrates another embodiment of an integrated OPV and OLED including a thin film battery between the OPV and the OLED.

FIG. 7 illustrates another embodiment of an integrated OPV and OLED including a common cathode having two reflective surfaces.

FIG. 8 illustrates another embodiment of an integrated OPV and OLED including a waveguide or resonant cavity.

FIG. 9 illustrates another embodiment of an integrated OPV and OLED including a common reflective surface for both the OPV and the OLED.

### DETAILED DESCRIPTION

### Introduction

All references cited herein are incorporated by reference in their entirely.

One embodiment is an integrated OPV and light emitting device comprising an OLED and an OPV. The OPV and OLED share a common substrate and can share an electrode. Multi-layer devices can be fabricated with many different layering designs.

The integrated devices would allow a significant cost savings because of the use of a single substrate or set of substrates, or a single encapsulation.

### Integrated OPV and OLED Generally

Regioregular polythiophenes and their copolymers can be used as hole transport layers (HTL) in integrated OPV and OLED devices.

The use of these materials in integrated OPV and OLED devices offers several desirable properties such as reduced cost of the device, increased luminescence of the device, lower threshold voltage, longer lifetime, ease of processability of materials and components during device production, the ability to use spin casting, drop casting, and printing techniques to apply the hole transport layer in integrated OPV and OLED devices, the ability to prepare more flexible integrated OPV and OLED devices, the ability to prepare low-weight integrated OPV and OLED devices, and the ability to prepare low-cost integrated OPV and OLED devices.

In the embodiments disclosed herein, an electroluminescent device converts current to electromagnetic radiation. This is accomplished when an electron and a positive charge or “hole” meet in an electroluminescent material creating an excited state species or exciton which emits a photon when it decays to the ground state. The value of such a device is that it is an efficient way to produce light at low voltage and minimal radiant heat. These devices currently find uses in many consumer electronics. The electroluminescent device is preferably an OLED.

Organic electroluminescent devices can take a variety of forms. Where the electroluminescence layer (ELL) comprises small molecules, typically vacuum deposited, the devices are commonly referred to as SMOLEDs.

One example of an integrated OPV and OLED device comprises seven components. Three of these components are electrodes. Two of these electrodes can be transparent conducting oxide surfaces, such as indium tin oxide (ITO), zinc oxide (ZnO), or fluorine-doped tin oxide (FTO). One of the transparent anode layers is coated onto a glass or plastic substrate, which functions as a charge carrier and allows emission of the photon from the device by virtue of its required transparency. The second transparent anode layer can be directly below the encapsulant such as glass. The third electrode is a cathode, and is frequently made of a low work function metal such as calcium or aluminum or both. This third electrode conducts or injects electrons into or out of the device.

The cathode can be between approximately 50 and 500 nm thick. The cathode is typically between approximately 50 and 250 nm thick. The cathode is more typically between approximately 80 and 200 nm thick. Between one of the transparent anode layers and cathode are the light emitter and the HTL. Between the cathode and the second transparent anode layer is an OPV active layer and a second HTL.

The fourth component of this embodiment is the light emitting material. The light emitter or emitting region can comprise, for example, materials based on polyphenylene vinylenes, polyfluorenes, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode. The light emitter can be between approximately 30 and 200 nm thick. The light emitter is typically between approximately 70 and 150 nm thick. The light emitter is more typically approximately 100 nm thick.

In this embodiment, a fifth and sixth component is an HTL material. The HTL is a conducting material that is able to transfer a positive charge or “hole” from the transparent anode to the ELL, creating the exciton which in turn leads to light emission. HTLs are typically p-doped or oxidized conductive materials that are generally chosen for the facility with which they are able to transfer a positive charge to the light emitter and the overall efficiency improvement they contribute to the device. The HTL is typically about between 30 and 200 nm thick. The HTL is more typically about between 30 and 80 nm thick.

In this embodiment, a seventh component is an OPV active layer. The OPV active layer is typically about between approximately 70 and 300 nm thick. The OPV active layer is typically approximately 180 nm thick. The active layer can comprise an n-type material and/or a p-type material. The p-type material can be an organic material including a polymeric material, although other types of p-type material are known in the art. For example, the p-type material can comprise a conjugated polymer or a conducting polymer, comprising a polymer backbone having a series of conjugated double bonds. It can be a homopolymer or a copolymer including a block copolymer or a random copolymer, or a terpolymer. Examples include polythiophene, polypyrrole, polyaniline, polyfluorene, polyphenylene, polyphenylene vinylene, and derivatives, copolymers, and mixtures thereof. The n-type material can be a fullerene, a derivative of a fullerence, or an n-type conducting polymer.

Soluble materials or well dispersed materials can be used in the stack to facilitate processing.

### OLED

One example of an OLED device comprises at least four components. Two of these components are electrodes, one anode and one cathode. Typically, the anode is a transparent anode such as indium tin oxide. The transparent anode layer can be coated onto a glass or plastic substrate, which functions as a charge carrier and allows emission of the photon from the device by virtue of its required transparency.

The second electrode is a cathode, and is frequently made of a low work function metal such as Ca, Al, or both. The cathode conducts or injects electrons into the device. Typically, the cathode is selected from the group consisting of Ba, Ca, LiF, Al, Ag, and combinations thereof. The cathode can be between approximately 50 and 500 nm thick. The cathode is typically between approximately 50 and 250 nm thick. The cathode is more typically about between approximately 80 and 200 nm thick. Between the transparent anode layer and the cathode are typically a light emitter and an HTL or HIL or both.

The light emitter can comprise, for example, materials based on polyphenylene vinylenes, polyfluorenes, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode. Typically, the light emitter can be a white light emitter if the device is used directly for lighting, or can be of any color if the device is used in a user configurable system that includes a plurality of devices (see, e.g., U.S. patent application Ser. No. 12/543,446, “User Configurable Mosaic Light Emitting Apparatus,” the disclosure of which is hereby incorporated by reference in its entirety). The light emitter can be between approximately 50 and 200 nm thick. The light emitter is typically between approximately 70 and 150 nm thick. The light emitter is more typically approximately 100 nm thick.

The OLED may optionally contain an additional Ba, Ca, or LiF layer. The Ba, Ca, or LiF layer could be between the cathode layer and the light emitter.

The coating of the light emitter can be followed by deposition of a commercial exciton blocking layer (EBL) and electron transport layer (ETL) and, then, a cathode layer that is 50 and 200 nm thick. The EBL can be a NiO layer for example. Typically, the cathode layer is between approximately 80 and 200 nm thick cathode layer. The cathode may be any appropriate cathode, including, for example, Ba, Ca, LiF, Al, Ag, and combinations thereof.

The HTL is a conducting material that is able to transfer a positive charge or “hole” from the transparent anode to the ELL, creating the exciton which in turn leads to light emission. In one embodiment, the HTL has exciton blocking functionality. HTLs are typically p-doped or oxidized conductive materials that are generally chosen for the facility with which they are able to transfer a positive charge to the light emitter and the overall efficiency improvement they contribute to the device. The HTL is typically about between 30 and 200 nm thick. The HTL is more typically about between 30 and 60 nm thick.

### OPV

One example of an OPV comprises at least four components. Two of these components are electrodes, one anode and one cathode. Typically, the anode is a transparent anode, such as ITO, ZnO, or FTO. The transparent anode layer can be coated onto a glass or plastic substrate, which functions as a charge carrier and allows entry of the photon into the device by virtue of its required transparency. The second electrode is a cathode, and is frequently made of a low work function metal such as calcium or aluminum or both. The cathode can be shared between the OPV and the OLED. The cathode can be between approximately 50 and 500 nm thick. Typically, the cathode is between approximately 50 and 250 nm thick. The cathode is more typically about between approximately 80 and 200 nm thick. Between the transparent anode layer and the cathode are an OPV and an HTL.

### OPV Active Layer

The OPV active layer is typically about between approximately 70 and 300 nm thick. The OPV active layer is more typically about between approximately 70 and 250 nm thick. The OPV active layer is most typically approximately 180 nm thick. The active layer can comprise an n-type material. The active layer can comprise a p-type material.

The active layer can comprise an n-type material as disclosed in patent application Ser. No. 11/743,587 filed May 2, 2007, to Laird, et al. (“ORGANIC PHOTOVOLTAIC DEVICES COMPRISING FULLERENES AND DERIVATIVES THEREOF”), which is hereby incorporated by reference in its entirety, including the description of the polymers, the figures, and the claims.

The active layer can comprise an n-type material comprising at least one fullerene structure. Fullerenes are known in the art. Fullerenes can be described as spheroidal carbon compounds. For example, the fullerene surface can present [6,6] bonding and [6,5] bonding as known in the art. The fullerene can have a surface comprising six-membered and five-membered rings. Fullerenes can be for example C60, C70, or C84, and additional carbon atoms can be added via derivative groups. See for example Hirsch, A.; Brettreich, M., Fullerenes: Chemistry and Reactions, Wiley-VCH Verlag, Weinheim, 2005, which is hereby incorporated by reference including teachings for fullerene nomenclature and synthesis, derivatization, reduction reactions (Chapter 2), nucleophilic additions (Chapter 3), cycloadditions (Chapter 4), hydrogenation (Chapter 5), radical additions (Chapter 6), transition metal complex formation (Chapter 7), oxidation and reactions with electrophiles (Chapter 8), halogenation (Chapter 9), regiochemistry (Chapter 10), cluster modification (Chapter 11), heterofullerenes (Chapter 12), and higher fullerenes (Chapter 13). Methods described herein can be used to synthesize fullerene derivatives and adducts.

The active layer material can be a copolymer comprising a first dithieno[3,2-b:2′,3′-d]pyrrole (DTP) repeat unit or a non-DTP repeat unit. Active layer materials can comprise materials as disclosed in provisional patent application Ser. No. 61/029,255 filed Feb. 15, 2008, to Sheina, (“NOVEL COMPOSITIONS, METHODS, AND POLYMERS”), which is hereby incorporated by reference in its entirety, including the description of the polymers, the figures, and the claims.

The active layer can comprise aryl-substituted conjugated polymers as disclosed in provisional patent application Ser. No. 60/938,166 filed May 15, 2007, to Sheina, et al. (“ARYL-SUBSTITUTED CONJUGATED POLYMERS”), which is hereby incorporated by reference in its entirety, including the description of the polymers, the figures, and the claims.

The p-type material can be an organic material including a polymeric material, although other types of p-type material are known in the art. For example, the p-type material can comprise a conjugated polymer or a conducting polymer, comprising a polymer backbone having a series of conjugated double bonds. It can be a homopolymer or a copolymer including a block copolymer or a random copolymer, or a terpolymer. Examples include polythiophene, polypyrrole, polyaniline, polyfluorene, polyphenylene, polyphenylene vinylene, and derivatives, copolymers, and mixtures thereof.

The p-type material can comprise a conjugated polymer soluble or dispersible in organic solvent or water. Conjugated polymers are described in for example T. A. Skotheim, Handbook of Conducting Polymers, 3^{rd} Ed. (two vol), 2007; Meijer et al., Materials Science and Engineering, 32 (2001), 1-40; and Kim, Pure Appl. Chem., 74, 11, 2031-2044, 2002. The p-type active material can comprise a member of a family of similar polymers which have a common polymer backbone but are different in the derivatized side groups to tailor the properties of the polymer. For example, a polythiophene can be derivatized with alkyl side groups including methyl, ethyl, hexyl, dodecyl, and the like.

Fullerenes and Fullerene Derivatives

The active layer can comprise at least one n-type material, wherein the n-type material comprises at least one derivatized fullerene or fullerene derivative. The derivative compound can be for example an adduct. The terms “derivatized fullerene,” “fullerene derivative” as used herein, can be used interchangeably and can be for example fullerenes comprising, from 1 to 84, or 1 to 70, or 1 to 60, from 1 to 20, from 1 to 18, from one to ten, or from one to six, or from one to five, or from one to three substituents each covalently bonded to, for example, one or two carbons in the spheroidal carbon compounds. The derivatized fullerene can comprise a fullerene covalently bonded by [4+2] cycloaddition to at least one derivative moiety, R.

Structures for the n-type material can be represented by:

F*—(R)n

and solvates, salts, and mixtures thereof,
wherein

n is at least one;

F is a spheroidal fullerene having a surface which comprises six-membered and five-membered rings; and

R comprises at least one optionally substituted, unsaturated or saturated, carbocyclic or heterocyclic first ring, wherein the first ring directly bonds to the fullerene.

An example of an embodiment wherein C60 is bonded to n R groups, and the bonding is generically represented by:

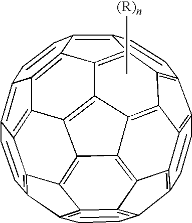

Copolymer Comprising DTP Repeat Unit

Copolymers and the DTP structure are generally known in the art. For example, homopolymers comprising the DTP structure in a repeat unit are known (References for homopolymers: (a) Berlin, A.; Pagani, G.; Zotti, G.; Schiavon, G. Makromol. Chem. 1992, 193, 399; (b) Pagani, G. A. Heterocycles 1994, 37, 2069; (c) Kenning, D. D.; Ogawa, K.; Rothstein, S. D.; Rasmussen, S. C. Polym. Mater. Sci. Eng. 2002, 86, 59; (d) Ogawa, K.; Rasmussen S. C. J. Org. Chem. 2003, 68, 2921), and these DTP structures can be used in copolymers as described herein.

In one example, poly(N-substituted dithieno[3,2-b:2′,3′-d]pyrrole)s (PDTPs) can be soluble conjugated polymers that have advantages over regioregular poly(3-alkylhiophene)s in terms of their reduced band gap energy and very stable oxidized state; see, for example, Ogawa et al., Macromolecules, 2006, 39, page 1771; Koeckelberghs et al., Macromolecules, 2005, 38, page 4545.

Examples of the DTP structure can be represented by:

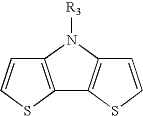

or more particularly,

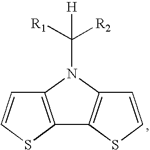

wherein R1, R2, and R3 can be, for example, any group which is compatible with the synthesis of DTP units and compatible with subsequent polymerization and copolymerization steps.

More particularly, R3 can be for example an optionally substituted alkyl, an optionally substituted aryl, an optionally substituted alkenyl, an optionally substituted alkynyl, and the like. R3 can bond to the pyrrole ring through a carbon atom. R3 can comprise one or more chiral centers.

Polythiophene

In particular, polythiophenes and derivatives thereof are known in the art. They can be homopolymers or copolymers, including block copolymers. They can be soluble or dispersible. They can be regioregular. In particular, optionally substituted-alkoxy- and optionally substituted alkyl-substituted polythiophenes can be used. In particular, regioregular polythiophenes can be used as described in for example U.S. Pat. Nos. 6,602,974 and 6,166,172 to McCullough et al., as well as McCullough, R. D.; Tristram-Nagle, S.; Williams, S. P.; Lowe, R. D.; Jayaraman, M. J. Am. Chem. Soc. 1993, 115, 4910, including homopolymers and block copolymers. See also Plextronics (Pittsburgh, Pa.) commercial products. Soluble alkyl- and alkoxy-substituted polymers and copolymers can be used including poly(3-hexylthiophene). Other examples can be found in U.S. Pat. Nos. 5,294,372 and 5,401,537 to Kochem et al. U.S. Pat. Nos. 6,454,880 and 5,331,183 further describe active layers.

It has been shown that, like other conjugated polymers, poly(thiophene) has a conjugated π-electron band structure that makes it a suitable p-type semiconductor for electroluminescent devices. Poly(thiophenes) can be prepared by various chemical and electrochemical transformations of suitably substituted thiophenes that result, primarily in the coupling of the thiophene rings at the 2- and 5-positions of the monomer. The degree of other modes of coupling of these thiophene moieties depends on the method employed and can afford polymers and/or oligomers of varying regioregularity. Regioregular syntheses of polythiophenes employ methods where the polymer exhibits nearly 100% of these 2- to 5-couplings, and embues the polymer with beneficial structural features as detailed below.

The degree of regioregularity can be, for example, about 80% or more, about 90% or more, about 95% or more, or about 98% or more.

Performance of these materials as a conductor of holes is increased when they are doped, or oxidized. Upon oxidation, electrons are removed from the valence band. This change in oxidation state results in the formation of new energy states, called bipolarons. The energy levels are accessible to some of the remaining electrons in the valence band, allowing the polymer to function as a conductor. The extent of this conjugated structure is dependent upon the polymer chains to form a planar conformation in the solid state. This is because conjugation from ring-to-ring is dependent upon π-orbital overlap. If a particular ring is twisted out of planarity, the overlap cannot occur and the conjugation band structure can be lost. Some minor twisting is not detrimental since the degree of overlap between thiophene rings varies as the cosine of the dihedral angle between them.

Performance of a conjugated polymer as a p-type semiconductor is also dependant upon the morphology of the polymer in the solid state. Electronic properties are dependent upon the electrical connectivity and inter-chain charge transport between polymer chains. Pathways for charge transport can be along a polymer chain or between adjacent chains. Transport along a chain requires a planar backbone conformation due to the dependence of the charge carrying moiety on the amount of double-bond character between the rings. This conduction mechanism between chains requires either a stacking of planar, polymer segment, called π-stacking, or an inter-chain hopping mechanism in which excitons or electrons can tunnel or “hop” through space or other matrix to another chain that is in proximity to the one that it is leaving. Therefore, any process that can drive ordering of polymer chains in the solid state helps to improve the performance of the conjugated polymer as component of an integrated OPV and OLED device. It is known that the absorbance characteristics of thin films of regioregular polythiophenes reflect the increased π-stacking which occurs in the solid state.

It has been shown that, like other conjugated polymers, poly(thiophene) has a conjugated π-electron band structure that, upon controlled oxidation, makes it a suitable p-type HTL for electroluminescent devices. Poly(thiophene) can be prepared by various chemical and electrochemical oxidations of thiophene that result, primarily in the coupling of the thiophene rings at the 2- and 5-positions.

The amount of π-overlap and charge density in this π-system also determines the energy of the π-π* transition for a conjugated polymer and influences the work function of the material in the solid state. Consequently, the nature of the p-type semiconductor determines the efficiency and performance of the organic electroluminescent device.

Polythiophenes can be homopolymers, copolymers, or block copolymers. Synthetic methods, doping, and polymer characterization, including regioregular polythiophenes with side groups, is provided in, for example, U.S. Pat. Nos. 6,602,974 to McCullough et al. and 6,166,172 to McCullough et al., which are hereby incorporated by reference in their entirety. Additional description can be found in the article, “The Chemistry of Conducting Polythiophenes,” by Richard D. McCullough, Adv. Mater. 1998, 10, No. 2, pages 93-116, and references cited therein, which is hereby incorporated by reference in its entirety. Another reference which one skilled in the art can use is the Handbook of Conducting Polymers, 2^{nd} Ed. 1998, Chapter 9, by McCullough et al., “Regioregular, Head-to-Tail Coupled Poly(3-alkylthiophene) and its Derivatives,” pages 225-258, which is hereby incorporated by reference in its entirety. This reference also describes, in chapter 29, “Electroluminescence in Conjugated Polymers” at pages 823-846, which is hereby incorporated by reference in its entirety.

Polythiophenes are described, for example, in Roncali, J., Chem. Rev. 1992, 92, 711; Schopf et al., Polythiophenes: Electrically Conductive Polymers, Springer: Berlin, 1997. See also for example U.S. Pat. Nos. 4,737,557 and 4,909,959.

Polymeric semiconductors are described in, for example, “Organic Transistor Semiconductors” by Katz et al., Accounts of Chemical Research, vol. 34, no. 5, 2001, page 359 including pages 365-367, which is hereby incorporated by reference in its entirety.

Block copolymers are described in, for example, Block Copolymers, Overview and Critical Survey, by Noshay and McGrath, Academic Press, 1977. For example, this text describes A-B diblock copolymers (chapter 5), A-B-A triblock copolymers (chapter 6), and -(AB)ₙ— multiblock copolymers (chapter 7), which can form the basis of block copolymer types in the embodiments disclosed herein.

Additional block copolymers including polythiophenes are described in, for example, Francois et al., Synth. Met. 1995, 69, 463-466, which is incorporated by reference in its entirety; Yang et al., Macromolecules 1993, 26, 1188-1190; Widawski et al., Nature (London), vol. 369, Jun. 2, 1994, 387-389; Jenekhe et al., Science, 279, Mar. 20, 1998, 1903-1907; Wang et al., J. Am. Chem. Soc. 2000, 122, 6855-6861; Li et al., Macromolecules 1999, 32, 3034-3044; Hempenius et al., J. Am. Chem. Soc. 1998, 120, 2798-2804;

The following article describes several types of regioregular systems beginning at page 97 and references cited therein: “The Chemistry of Conducting Polythiophenes,” by Richard D. McCullough, Adv. Mater. 1998, 10, No. 2, pages 93-116. In a regioregular polymer, including a polythiophene, the degree of regioregularity can be, for example, about 90% or more, or about 95% or more, or about 98% or more, or about 99% or more. Methods known in the art such as, for example, NMR can be used to measure the degree of regioregularity. Regioregularity can arise in multiple ways. For example, it can arise from polymerization of asymmetric monomers such as a 3-alkylthiophene to provide head-to-tail (HT) poly(3-substituted)thiophene. Alternatively, it can arise from polymerization of monomers which have a plane of symmetry between two portions of monomer such as for example a bi-thiophene, providing for example regioregular HH-TT and TT-HH poly(3-substituted thiophenes).

In particular, substituents which can be used to solubilize conducting polymers with side chains include alkoxy and alkyl including for example C1 to C25 groups, as well as heteroatom systems which include for example oxygen and nitrogen. In particular, substituents having at least three carbon atoms, or at least five carbon atoms can be used. Mixed substituents can be used. The substituents can be nonpolar, polar or functional organic substitutents. The side group can be called a substituent R which can be for example alkyl, perhaloalkyl, vinyl, acetylenic, alkoxy, aryloxy, vinyloxy, thioalkyl, thioaryl, ketyl, thioketal, and optionally can be substituted with atoms other than hydrogen.

Thiophene polymers can be star shaped polymers with the number of branches being for example more than three and comprising thiophene units. Thiophene polymers can be dendrimers. See for example Anthopoulos et al., Applied Physics Letters, 82, 26, Jun. 30, 2003, 4824-4826, and further description of dendrimers hereinafter.

Aryl-Substituted Conjugated Polymers

The aryl-substituted conjugated polymers can include a conjugated backbone that includes heterocyclic repeat units and side groups attached to at least some of the heterocyclic repeat units. At least some of the side groups on the heterocyclic repeat units are aryl groups which are desirably attached directly to the aryl rings, where “aryl” refers to a cyclic, aromatic arrangement of carbon atoms forming a ring. At least some of the aryl groups have at least one branched alkyl substituent attached thereto.

The polymer backbone may be homopolymeric or copolymeric. Copolymeric polymer backbones are those that include at least two different repeat units. In these embodiments, monomers other than those containing the aryl-substituted heterocyclic repeat units having a branched alkyl substituent on the aryl ring are referred to as comonomers. The copolymers may be block, alternating, graft or random copolymers and the comonomers may be non-heterocyclic, substituted heterocyclic and/or unsubstituted heterocyclic. For example, the block copolymers may be AB type or ABA type. The number of different comonomers in the copolymers may be one, two, three, or more. In some embodiments, the polymer is a copolymer that includes differently-substituted thiophene rings and/or a combination of substituted and unsubstituted thiophene rings.

Polythiophenes, and particularly regioregular polythiophenes, are well-suited for the present applications because polythiophenes have a conjugated π-electron band structure that makes them strong absorbers of light in the visible spectrum and hence a candidate p-type semiconductor for photovoltaic cells. In the case of poly(3-alkyl thiophenes), the alkyl substituents that are typically included to increase solubility of the polymer in common organic solvents have an electron-releasing effect, raising the HOMO of the polymer relative to that of poly(thiophene).

The polythiophenes may be, for example, polythiophenes having the following structure:

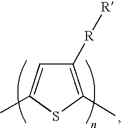

wherein R is an aryl group, R′ is a branched alkyl group, and n represents the number of thiophene repeat units in the polymer backbone. The thiophene repeat units may be adjacent (as in the case wherein the polymer backbone is homopolymeric) or may be separated by other backbone units (as in the case wherein the polymer backbone is copolymeric (e.g., block co-polymeric)). Typically, n has a value of about 5 to about 3,000, or about 10 to about 1,000, or about 10 to about 300, or about 50 to about 200. Although the structure above shows the thiophene ring substituted with an aryl group at the 3-position, the ring could be substituted with an aryl group at positions other than, or in addition to, the 3-position. For example, the aryl group may be located at the 4-position of the heterocyclic ring.

### Lighting Device

In one embodiment, a device comprises an integrated OPV and OLED.

In one embodiment, a lighting device comprises an integrated OPV and electroluminescent device comprising: an OLED comprising a white light emitter and a first HIL and/or HTL layer; and an OPV comprising an active layer and a second HIL and/or HTL layer; wherein the OLED and the OPV share a common substrate building layer and a common cathode.

The device can be adapted to be a lighting device. For example, the device can be adapted to not be a display. OLEDs can provide lighting that is warm and inviting and is closer to natural light. Additionally, OLEDs can provide sources of lighting that are cost-efficient, energy efficient, and environmentally friendly.

Additionally, lighting device designs differ fundamentally from the designs used in OLEDs used in flat-panel displays. See, for example, Kincade, Kathy “OLEDS bring the sunshine in” Laser Focus World, June 2004, which is hereby incorporated by reference. For example, displays can have rows and columns of pixels that emit light of different colors. Lighting devices do not utilize pixels to generate light. Other differences between lighting devices and displays are known in the art.

### Stacked Integrated OPV and OLED Device

In one embodiment, an integrated OPV and electroluminescent device comprises an OLED and an OPV, wherein the OLED and the OPV share a common substrate and share a cathode, wherein the OLED comprises a light emitter and a first HTL layer comprising a regioregular polythiophene, and wherein the OPV comprises an active layer and a second HTL layer comprising a regioregular polythiophene.

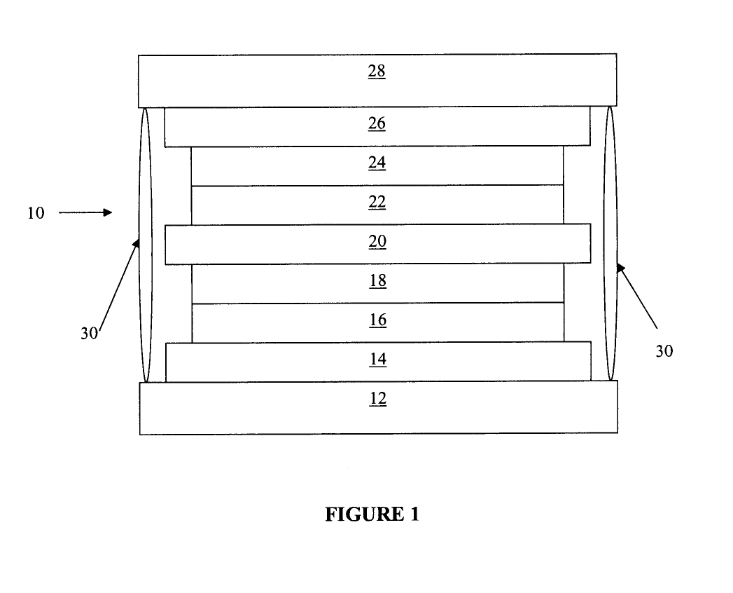

As illustrated in FIG. 1, an integrated OPV and OLED 10 is provided. A substrate building layer 12 is provided. Substrate building layer 12 typically is the layer that the rest of the device is built upon. Substrate building layer 12 can be any appropriate substrate. Typically, substrate building layer 12 is glass or plastic. Substrate building layer 12 is coated with a transparent conductor 14. FIG. 1 and element 12 provides an example of a common substrate building layer.

The transparent conductor 14 can be indium tin oxide. The transparent conductor can include carbon nanotubes, patterned metallic lines or arrays, or high conductivity films of conducting polymers (e.g. PEDOT) that may also be combined with patterned metallic lines or arrays to increase conductivity.

Transparent conductor 14 can be an anode and function as a charge carrier and allows emission of the photon from the device by virtue of its required transparency.

Transparent conductor 14 is coated with a HTL material 16. HTL 16 is a conducting material that is able to transfer a positive charge or “hole” from the transparent anode to the light emitting layer 18, creating the exciton which in turn leads to light emission. HTL 16 can comprise a regioregular polythiophene. HTL 16 is able to transfer a positive charge to the light emitter and the overall efficiency improvement they contribute to the device. A light emitter 18 is coated on top of HTL 16. The light emitter 18 can comprise, for example, materials based on polyphenylene vinylenes, polyfluorenes, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode.

A cathode layer 20 is deposited on light emitter 18. Cathode layer 20 conducts or injects electrons into or out of the device. An OPV active layer 22 is coated on top of cathode layer 20. The OPV active layer 22 comprises a composition mixture comprising at least one p-type material and at least one n-type material. The OPV active layer 22 can be then deposited by spin casting, ink jetting, doctor blading, spray casting, dip coating, vapor depositing, or any other known deposition method, on top of cathode layer 20.

OPV active layer 22 is coated with a second HTL layer 24. Second HTL 24 can comprise a regioregular polythiophene.

Second HTL 24 is coated with a second transparent conductor 26. Typically second transparent conductor 26 can be indium tin oxide, but can also be other materials as discussed above with the first transparent conductor. Second transparent conductor 26 is an anode. Second transparent conductor 26 functions as a charge carrier and allows transmission of photons into the device by virtue of its required transparency. An encapsulant 28 is above the second transparent conductor 26. Encapsulant 28 can be any appropriate material to encapsulate the device 10. Typically encapsulant 28 is glass or plastic. Sealant 30 encapsulates and seals the device 10. Typically, sealant 30 has good encapsulating properties, such as a curable glue, or other epoxy or plastic coatings. Cavity glass with a getter/dessicant may also be used.

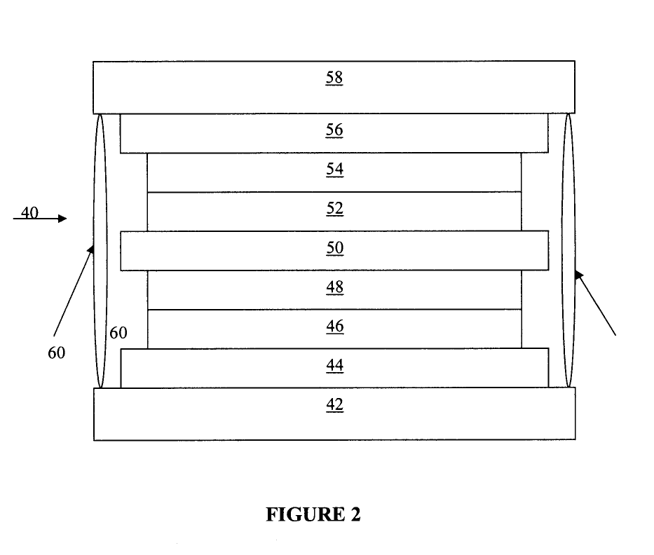

As illustrated in FIG. 2, another embodiment of an integrated OPV and OLED 40 is provided. A substrate building layer 42 is provided. The substrate building layer 42 can be any appropriate substrate. Substrate building layer 42 typically is the layer that the rest of the device is built upon. Typically, substrate building layer 42 is glass or plastic. Substrate building layer 42 is coated with a transparent conductor 44. Typically transparent conductor 44 can be indium tin oxide or other suitable materials. Transparent conductor 44 is an anode. Transparent conductor 44 functions as a charge carrier and allows transmission of photons into the device by virtue of its required transparency. FIG. 2 and element 42 provide another example of a common substrate building layer.

Transparent conductor 44 is coated with a HTL material 46. HTL 46 can comprise a regioregular polythiophene. An OPV active layer 48 is coated on top of HTL 46. HTL 46 is able to transfer a positive charge from OPV active layer 48 and the overall efficiency improvement they contribute to the device. The OPV active layer 48 comprises a composition mixture comprising at least one p-type material and at least one n-type material. The OPV active layer 48 can be then deposited by spin casting, ink jetting, doctor blading, spray casting, dip coating, vapor depositing, or any other known deposition method, on top of HTL 46.

A cathode layer 50 is deposited on OPV active layer 48. Cathode layer 50 conducts or injects electrons into or out of the device. A light emitter or emitting region 52 is coated on top of cathode layer 50. The light emitter 52 can comprise, for example, materials based on polyphenylene vinylenes, polyfluorenes, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode.

The light emitter 52 is coated with a second HTL layer 54. Second HTL layer 54 is a conducting material that is able to transfer a positive charge or “hole” from the transparent anode, creating the exciton which in turn leads to light emission. Second HTL 54 comprises a regioregular polythiophene. Second HTL 54 is able to transfer a positive charge to the light emitter and the overall efficiency improvement they contribute to the device.

Second HTL 54 is coated with a second transparent conductor 56. Typically second transparent conductor 56 can be indium tin oxide or other suitable materials. Second transparent conductor 56 is an anode. Second transparent conductor 56 functions as a charge carrier and allows emission of the photon from the device by virtue of its required transparency. An encapsulant 58 is above the second transparent conductor 56. Encapsulant 58 can be any appropriate material to encapsulate the device 40. Typically encapsulant 58 is glass or plastic. Sealant 60 encapsulates and seals the device 40. Typically, sealant 60 has good encapsulating properties, such as a curable glue, or other epoxy or plastic coatings. Cavity glass with a getter/dessicant may also be used.

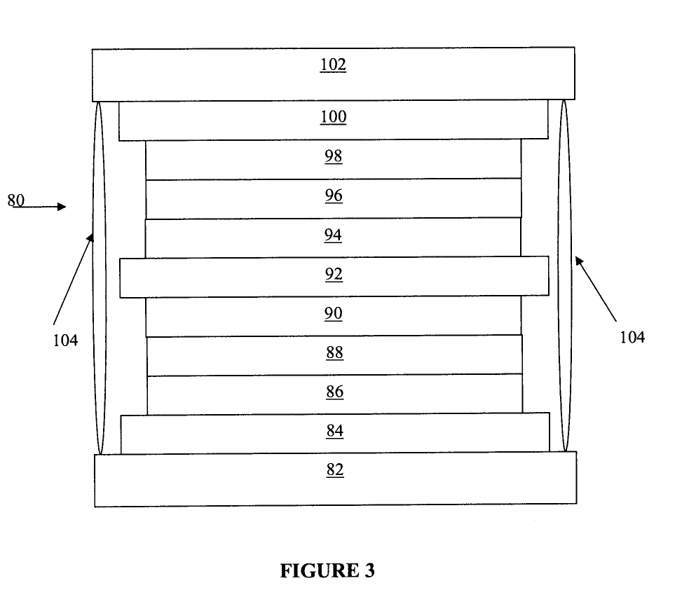

As illustrated in FIG. 3, an integrated OPV and OLED 80 is provided. A substrate building layer 82 is provided. Substrate building layer 82 typically is the layer that the rest of the device is built upon. The substrate building layer 82 can be any appropriate substrate. Typically, substrate building layer 82 is glass or plastic. Substrate building layer 82 is coated with a transparent conductor 84. Typically transparent conductor 84 can be indium tin oxide other suitable materials. Transparent conductor 84 is an anode. Transparent conductor 84 functions as a charge carrier and allows transmission of photons therethrough. Again, element 82 and FIG. 3 provide an example of a common substrate building layer.

Transparent conductor 84 is coated with a HTL material 86. HTL 86 is a conducting material that is able to transfer a positive charge or “hole” from the transparent anode to the ELL, creating the exciton which in turn leads to light emission. HTL 86 can comprise a regioregular polythiophene. HTL 86 is able to transfer a positive charge to a light emitter 88 and the overall efficiency improvement they contribute to the device. Light emitter 88 is coated on top of HTL 86. The light emitter 88 can comprise, for example, materials based on polyphenylene vinylenes, polyfluorenes, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode.

A Ba, Ca, or LiF interlayer 90 is deposited on light emitter 88. An Al cathode layer 92 is deposited on the interlayer 90. Al cathode layer 92 conducts or injects electrons into the device. A second Ba, Ca, or LiF interlayer 94 is deposited on Al cathode layer 92. An OPV active layer 96 is coated on top of the second interlayer 94. The OPV active layer 96 comprises a composition mixture comprising at least one p-type material and at least one n-type material. The OPV active layer 96 can be then deposited by spin casting, ink jetting, doctor blading, spray casting, dip coating, vapor depositing, or any other known deposition method, on top of the second interlayer 94.

OPV active layer 96 is coated with a second HTL layer 98. Second layer HTL 98 can comprise a regioregular polythiophene.

Second HTL 98 is coated with a second transparent conductor 100. Second transparent conductor 100 is an anode. Second transparent conductor 100 functions as a charge carrier and allows transmission of photons into the device by virtue of its required transparency. An encapsulant 102 is above the second transparent conductor 100. Encapsulant 102 can be any appropriate material to encapsulate the device 80. Typically encapsulant 102 is glass or plastic. Sealant 104 encapsulates and seals the device 80. Typically, sealant 104 has good encapsulating properties, such as a curable glue, or other epoxy or plastic coatings. Cavity glass with a getter/dessicant may also be used.

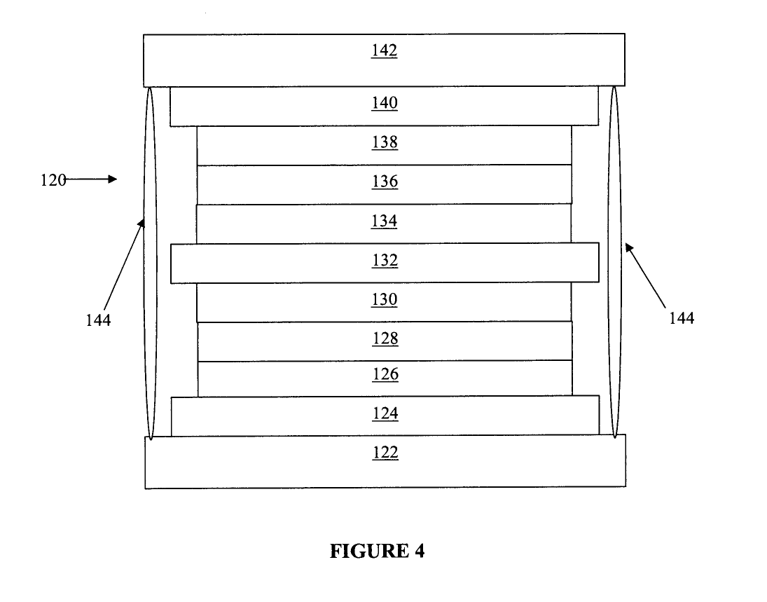

As illustrated in FIG. 4, another embodiment of an integrated OPV and OLED 120 is provided. A substrate building layer 122 is provided. The substrate building layer 122 can be any appropriate substrate. Typically, substrate building layer 122 is glass or plastic. Substrate building layer 122 is coated with a transparent conductor 124. Transparent conductor 124 is an anode. Transparent conductor 124 functions as a charge carrier and allows transmission of photons into the device by virtue of its required transparency. Again, FIG. 4 and element 122 provide an example of a common substrate building layer.

Transparent conductor 124 is coated with a HTL material 126. HTL 126 is a conducting material. HTL 126 can comprise a regioregular polythiophene. An OPV active layer 128 is coated on top of HTL 126. HTL 126 is able to transfer a positive charge from OPV active layer 128 and the overall efficiency improvement they contribute to the device. The OPV active layer 128 comprises a composition mixture comprising at least one p-type material and at least one n-type material. The OPV active layer 128 can be deposited by spin casting, ink jetting, doctor blading, spray casting, dip coating, vapor depositing, or any other known deposition method, on top of HTL 126.

A Ba, Ca, or LiF interlayer 130 is deposited on OPV active layer 128. A cathode layer 132 is deposited on the interlayer 130. The cathode layer 132 conducts or injects electrons into or out of the device. A second Ba, Ca, or LiF interlayer 134 is deposited on cathode layer 132. An OLED layer 136 is coated on top of the second interlayer 134. The OLED layer 136 can comprise, for example, materials based on polyphenylene vinylenes, polyfluorenes, and organic-transition metal small molecule complexes. These materials are generally chosen for the efficiency with which they emit photons when an exciton relaxes to the ground state through fluorescence or phosphorescence and for the wavelength or color of the light that they emit through the transparent electrode.

The organic light emitting layer 136 is coated with a second HTL layer 138. Second HTL layer 138 is a conducting material that is able to transfer a positive charge or “hole” from the transparent anode, creating the exciton which in turn leads to light emission. Second HTL 138 can comprise a regioregular polythiophene. Second HTL 138 is able to transfer a positive charge to the light emitter and the overall efficiency improvement they contribute to the device.

Second HTL 138 is coated with a second transparent conductor 140. Second transparent conductor 140 is an anode. Second transparent conductor 140 functions as a charge carrier and allows emission of the photon from the device by virtue of its required transparency. An encapsulant 142 is above the second transparent conductor 140. Encapsulant 142 can be any appropriate material to encapsulate the device 120. Typically encapsulant 142 is glass or plastic. Sealant 144 encapsulates and seals the device 120. Typically, sealant 144 has good encapsulating properties, such as a curable glue, or other epoxy or plastic coatings. Cavity glass with a getter/dessicant may also be used.

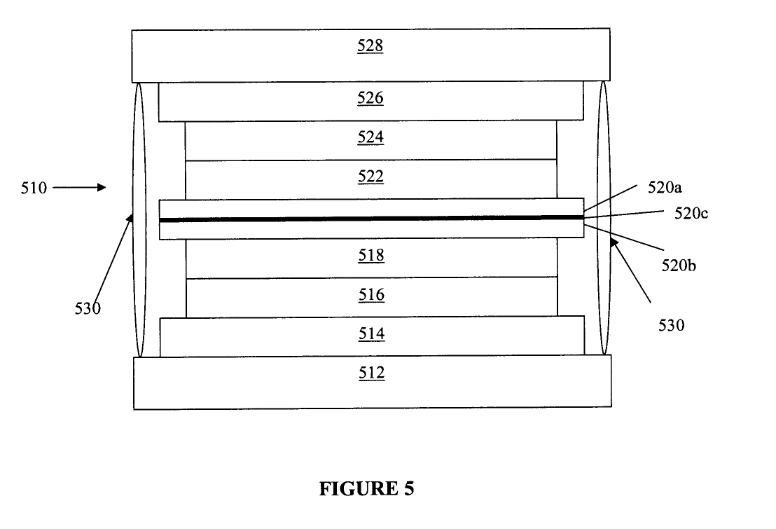

As illustrated in FIG. 5, another embodiment of integrated OPV and OLED 510 is provided. A substrate building layer 512 is provided. Substrate building layer 512 typically is the layer that the rest of the device is built upon. Substrate building layer 512 is coated with a transparent conductor 514. Transparent conductor 514 is an anode.

Transparent conductor 514 is coated with a HTL material 516. A light emitter 518 is coated on top of HTL 516.

A cathode layer 520b is deposited on light emitter 518. Cathode layer 520b conducts or injects electrons into the device. An OPV layer 522 is coated on top of another cathode layer 520a. The two cathode layers 520a, 520b are separated by an insulating layer 520c. Insulating layer 520c may comprise plastic, SiO₂, or another suitable insulator and permits additional freedom in laterally patterning the OPV and OLED regions. OPV active layer 522 is coated with a second HTL layer 524.

Second HTL 524 is coated with a second transparent conductor 526. An encapsulant 528 is above the second transparent conductor 526. Sealant 530 encapsulates and seals the device 510.

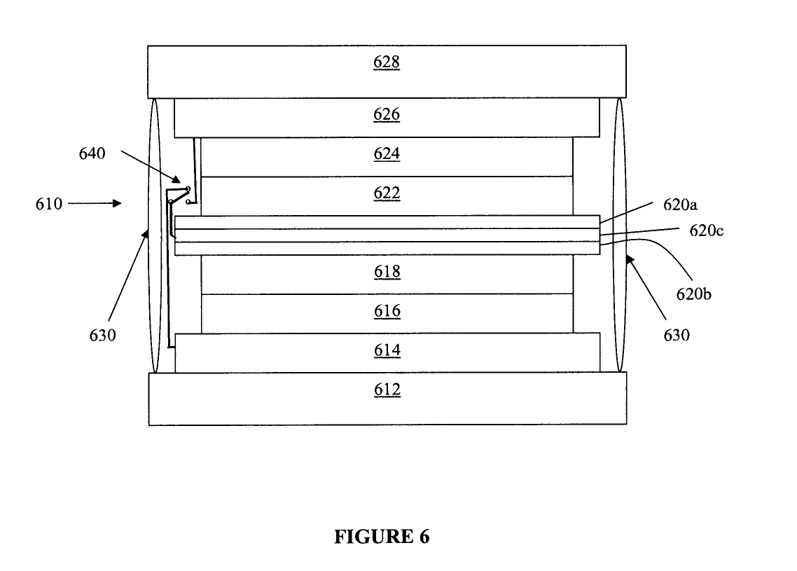

As illustrated in FIG. 6, another embodiment of integrated OPV and OLED 610 is provided. A substrate building layer 612 is provided. Substrate building layer 612 is coated with a transparent conductor 614.

Transparent conductor 614 is coated with a HTL material 616. A light emitting region or layer 618 is coated on top of HTL 616.

A cathode layer 620b is deposited on light emitter 618. An OPV layer 622 is coated on top of another cathode layer 620a. A battery 620c is disposed between the two cathode layers 620a, 620b. The two cathode layers 620a, 620b can be separated from the battery 620c by two insulating layers (not shown). The device can further comprise a switch 640 configured to flip the thin film battery from receiving charge from the OPV to delivering charge to the OLED, or vice versa.

OPV active layer 622 is coated with a second HTL layer 624. Second HTL 624 is coated with a second transparent conductor 626. Second transparent conductor 626 is an anode. An encapsulant 628 is above the second transparent conductor 626. Sealant 630 encapsulates and seals the device 610.

FIGS. 5 and 6 show in elements 512 and 612, respectively, examples, of common substrate building layers.

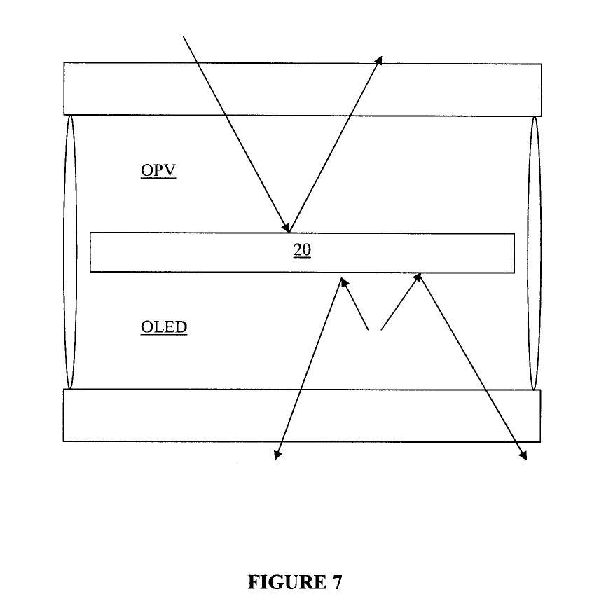

In the embodiment shown in FIG. 1, the OLED and the OPV shares a common cathode 20. As illustrated in FIG. 7, the common cathode 20 can have two reflective surfaces configured to reflect light into the OLED and the OPV, respectively, thereby improving the light out-coupling efficiency and the light conversion efficiency at the same time. This can be achieved, for example, by making the cathode layer 20 with Al, which naturally has two reflective surfaces. In addition, reflective layers such as distributed Bragg reflectors (DBR) can be employed.

A light coupling layer can be disposed on the top surface of the OPV to improve the inward coupling of light. The light coupling layer can comprise, for example, an antireflection (AR) coating, a grating, a photonic crystal, or a microlens array.

Alternative to having a common cathode, the OLED and the OPV can share a common anode.

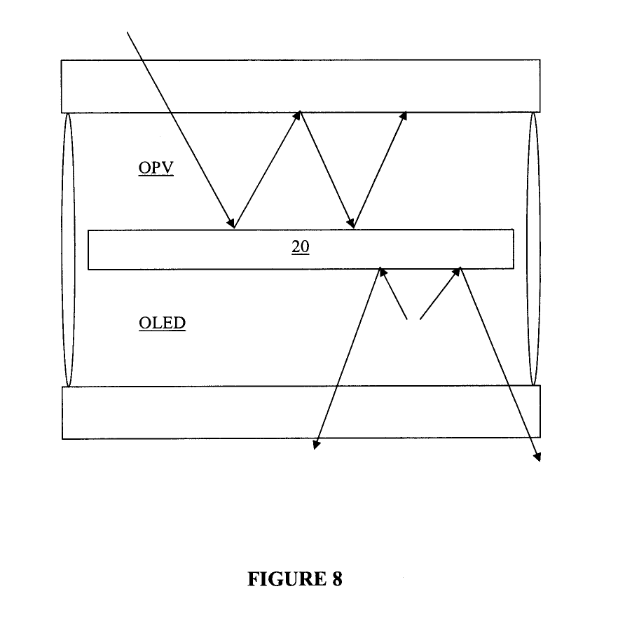

In the embodiment shown in FIG. 8, the OPV can comprise a waveguide or a resonant cavity configured to reflect light multiple times within the OPV to improve light conversion efficiency. The waveguide or resonant cavity can be optimized to reflect light through the OPV active layer at wavelengths that have higher quantum efficiency, for example, between 500 nm and 900 nm. In this range, the OPV active layers can have absorption peaks.

The OLED can also comprise a light out-coupling layer to further improve light out-coupling efficiency at desired emission wavelengths.

The OLED can comprise a white light emitting region, or a colored light emitting region.

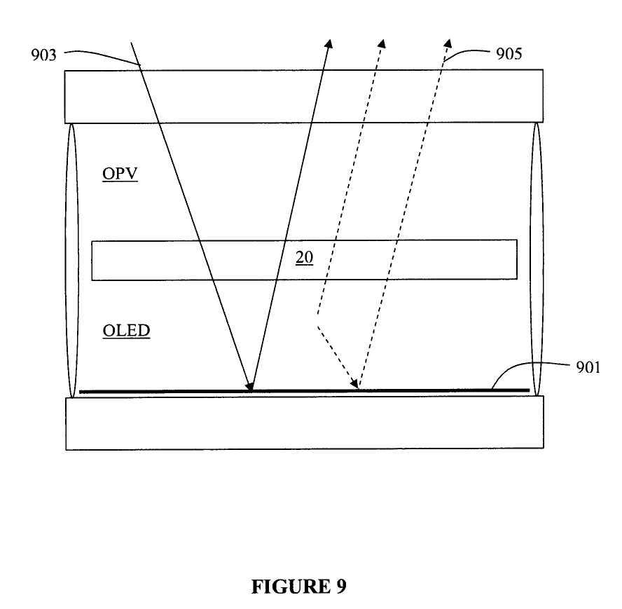

In another embodiment shown in FIG. 9, the common cathode 20 can be substantially transparent, and a reflective surface 901 is disposed at the bottom surface of the integrated device. Both the OPV and the OLED can benefit from the reflective surface 901. For example, the OLED layers and the common cathode 20 can both be substantially transparent to the ambient light 903, which can be reflected by the reflective surface 901 and pass the OPV at least one more time. This can be achieved, for example, by having a wavelength mismatch between photons that are most effectively absorbed by the OPV active layer (e.g., 600 nm-900 nm) and the photons emitted by the OLED (e.g., 400 nm-600 nm).

The light entering the OPV layer can be red shifted to improve the wavelength mismatch between the OPV and the OLED. The light can be red shifted, for example, using quantum dots, as described in U.S. patent application Ser. No. 11/970,485 (“Quantum Dot Photovoltaic Device”), filed on Jan. 7, 2008, the disclosure of which is hereby incorporated by reference in its entirety.

It is noted that in the embodiments illustrated in FIGS. 7-9, the positions of the OPV and the OLED can be switched. For example, the OLED can be on top of the OPV.

The integrated device can be configured as a modular chip. A plurality of such modular chips can be assembled, or configured by user, into a lighting system. The plurality of lighting devices can include devices of different colors, and the lighting system can configured to produce white light in a far-field.

At least some of the plurality of lighting devices can be configured to be removably mechanically and electrically coupled to each other. The lighting system can further comprise a mount, wherein at least some of the plurality of lighting devices are configured to be removably mechanically and electrically coupled to the mount. The modular chip concept, and systems and products formed with the modular chips, have been described in related applications including U.S. patent application Ser. Nos. 12/543,225 (“Organic Light Emitting Diode Lighting Devices”), 12/543,440 (“Organic Light Emitting Diode Lighting Systems”), 12/543,442 (“Organic Light Emitting Diode Products”), and 12/543,446 (“User Configurable Mosaic Light Emitting Apparatus”), the disclosures of these applications being incorporated by reference in their entirety.

In the embodiment where the OPV and the OLED share a common cathode, the lateral dimension of the individual modular chips may be limited by the resistance of the common or the transparent electrode. Accordingly, the modular chip can each have a lateral dimension smaller than about two inches.

Alternatively, an apparatus with large-area active layers, or multiple-region active layers can be provided. For example, a plurality of OPV regions can be configured to be serially connected to produce a useful output voltage for charging a battery. In particular, the plurality of OPV regions are configured to be serially connected to produce a peak voltage of 18-24 V.

A plurality of OLED regions can configured to be connected in parallel to permit application of a substantially equal voltage and useful current density to the plurality of OLED regions. For example, the plurality of OLED regions can be configured to be connected in parallel to permit application of a substantially equal voltage of 4-10 V and useful current density of 20-100 mA/cm² to the plurality OLED regions.

At least some of the plurality of OLED regions can have different colors, and wherein the apparatus is configured such that a far field light field is substantially white.

A variety of OLED device stack structures can benefit from the embodiments disclosed herein. Thus, the device, apparatus, and system structures are not limited to those described herein and shown in the drawings, which are merely some specific examples. For example, additional OLED stacks could include more complicated electron and hole transport and blocking layers (typically vapor deposited), For example, PIN-OLED structures (developed by companies such as Novaled), and vertically stacked OLEDs including multiple emitting layers in the OLED stack can be combined with the concepts disclosed herein.

In addition, a variety of other printable photovoltaic technologies can take advantage of the device structures and concepts disclosed herein. For example, other organic photovoltaic technologies such as the Graetzel cell or the dye-sensitized solar cell and other thin-film inorganic technologies including printable silicon, CIGS, CIS or CdTe, can be included in the device structures disclosed herein.

One embodiment provides an integrated OPV and electroluminescent device comprising: an OLED comprising a white light emitter; and an OPV comprising an active layer; wherein the OLED and the OPV share a common substrate building layer and a common cathode; and wherein the device is adapted to be a lighting device.

In one embodiment, the OLED comprises a white light emitter.

Another embodiment comprises an integrated OPV and OLED device in which the OPV and the OLED share a common substrate building layer and a single cathode and wherein the OPV is stacked on top of the OLED.

Another embodiment comprises an integrated OPV and OLED device in which the OPV and the OLED share a common substrate building layer and a single cathode and wherein the OLED is stacked on top of the OPV.

In another embodiment, the OLED comprises a white light emitter, and the OPV comprises an active layer. In one embodiment, the OLED is closer to the substrate building layer than the OPV. Optionally, the OPV is stacked on top of the OLED.

In an alternative embodiment, the OPV is closer to the substrate than the OLED. In one embodiment the OLED is stacked on top of the OPV.

In one embodiment, the cathode is selected from the group comprising Ba, Ca, LiF, Al, Ag, and combinations thereof. In another embodiment, the cathode is layered above a separate Ba, Ca, or LiF interlayer, and a second separate Ba, Ca, or LiF interlayer is layered on top of the cathode.

In one embodiment, the light emitter comprises materials based on polyphenylene vinylenes, polyfluorenes, and/or organic-transition metal small molecule complexes.

In another embodiment, the OPV active layer comprises an n-type or p-type material.

In one embodiment, the HTL comprises a regioregular polythiophene. In one embodiment, the degree of regioregularity of the regioregular polythiophene is approximately 90%. In another embodiment, the degree of regioregularity of the regioregular polythiophene is approximately 95%. In another embodiment, the regioregular polythiophene is a block polymer.

Another embodiment provides an integrated OPV and electroluminescent device comprising: an OLED and an OPV, wherein the OLED comprises; an indium tin oxide layer; an HTL (hole transport layer) layer; a light emitter; and an Al cathode; and the OPV comprises: an OPV active layer; an HTL layer; and an indium tin oxide layer, and wherein the OLED and OPV share a single substrate and the Al cathode.

Another embodiment provides methods of making an integrated OPV and organic white light emitting device.

A device comprising an integrated OPV and electroluminescent device including: an OLED comprising a white light emitter; and an OPV comprising an active layer; wherein the OLED and the OPV share a common substrate building layer and a common cathode; and wherein the device is adapted to be a lighting device.

In another embodiment, an integrated OPV and electroluminescent device is provided, comprising: an OLED comprising; an indium tin oxide layer; a HTL layer comprising a regioregular polythiophene; a light emitter; and a cathode; an OPV comprising; an OPV active layer; a HTL layer comprising a regioregular polythiophene; and an indium tin oxide layer, wherein the OLED and OPV share a single substrate and the cathode.

In another embodiment, a method for making an integrated OPV and electroluminescent device, comprising: providing a substrate; providing a substrate building layer optionally comprising a first transparent conductor; providing a first HTL; providing a light emitter; providing a cathode; providing an OPV active layer; providing a second HTL; providing a second transparent conductor; providing an encapsulant; and combining the substrate building layer, the first transparent conductor, the first HTL, the light emitter, the cathode, the OPV active layer, the second HTL, the second transparent conductor, and the encapsulant. The light emitter may be a white light emitter. Typically, the light emitter is a white light emitter.

The first transparent conductor may be indium tin oxide and the second transparent conductor may be indium tin oxide. The substrate building layer may comprise the first transparent conductor. Alternatively, the first transparent conductor may be a separate layer in the device.

In one embodiment, the layering on the substrate occurs in the order: the first transparent conductor; the HTL comprising a regioregular polythiophene; the light emitter; the cathode; the OPV active layer; the second HTL comprising a regioregular polythiophene; the second transparent conductor; and the encapsulant.

In another embodiment, the layering on the substrate occurs in the order: the first transparent conductor; the HTL comprising a regioregular polythiophene; the OPV active layer; the cathode; the light emitter; the second HTL comprising a regioregular polythiophene; the second transparent conductor; and the encapsulant.

In some embodiments, the device can comprise an n-type semiconducting transparent oxide layer as an optional interlayer on the cathode as an electron transport layer. The device can comprise a TiO₂ or ZnO layer as an optional interlayer on the cathode as an electron transport layer.

In some embodiments, the cathode can be layered above a first interlayer comprising Ba, Ca, or LiF, or combinations thereof, and a second interlayer comprising Ba, Ca, or LiF, or combinations thereof, which is layered on top of the cathode. The cathode can be layered above a first Ba, Ca, or LiF layer that is approximately 5 to 10 nm thick.

In some embodiments, the OPV can further comprise an electron blocking NiO layer.

### EXAMPLES

### Example A

The device fabrication described below is intended as an example and does not in any way imply the limitation of the embodiments to the said fabrication process, device architecture (sequence, number of layers etc.) or materials.

The OPV and organic light emitting diode (OPV/OLED) devices described herein can be fabricated on a transparent conducting oxide surfaces, such as indium tin oxide (ITO), zinc oxide (ZnO), or fluorine-doped tin oxide (FTO), deposited on a glass substrate. The cleaned substrate can then be coated with a first HTL. The first HTL film is between approximately 30 and 200 nm thick. The coating process can be done on a spin coater but can easily be similarly achieved with spray coating, ink-jetting, contact printing or any other deposition method capable of resulting in an HTL film of the desired thickness. This can be followed by the spin coating of the light emitting layers, which in this example is a commercial white light emitter. The light emitter can be measured to be approximately 100 nm thick.

The coating of the light emitter can be followed by deposition of a commercial EBL and an ETL and, then, an approximately 80-200 nm thick Al cathode layer. The Al cathode layer then can be coated with an OPV active layer comprising a composition mixture comprising at least one p-type material and at least one n-type material. The OPV active layer can be deposited by spin casting, ink jetting, doctor blading, spray casting, dip coating, vapor depositing, or any other known deposition method, on top of the Al cathode layer.

The OPV active layer can be coated with a second HTL surface. The second HTL film is between approximately 30 and 200 nm thick. The coating process can be done on a spin coater but can easily be similarly achieved with spray coating, ink-jetting, contact printing or any other deposition method capable of resulting in an HTL film of the desired thickness.

A second ITO surface can be deposited on the second HTL surfaces. The device can be then encapsulated using a glass cover slip sealed with a curable glue, or other epoxy or plastic coatings. Cavity glass with a getter/desiccant may also be used.

### Example B

The device fabrication described below is intended as an example and does not in any way imply the limitation of the embodiments to the said fabrication process, device architecture (sequence, number of layers etc.) or materials.

The OPV/OLED devices described herein can be fabricated on indium tin oxide (ITO) surfaces deposited on glass substrates. The cleaned substrates can be coated with a first HTL. The first HTL film is between approximately 30 and 200 nm thick. The coating process can be done on a spin coater but can easily be similarly achieved with spray coating, ink-jetting, contact printing or any other deposition method capable of resulting in an HTL film of the desired thickness. This can be followed by the spin coating of the light emitting layers, which in this example is a commercial white light emitter polymer. The white light emitter can be measured to be approximately 100 nm thick.

The coating of the polymer layers can be followed by deposition of a Ba, Ca, or LiF layer and then an approximately 80-200 nm Al cathode layer. The Al cathode layers can be coated with an OPV active layer comprising a composition mixture comprising at least one p-type material and at least one n-type material. The OPV active layers then can be deposited by spin casting, ink jetting, doctor blading, spray casting, dip coating, vapor depositing, or any other known deposition method, on top of the HTL film. The deposition of the OPV active layers can be followed by deposition of a second Ba, Ca, or LiF layer.

The OPV active layers can be coated with a second HTL surfaces. The coating process can be done on a spin coater, or can easily be similarly achieved with spray coating, ink-jetting, contact printing or any other deposition method capable of resulting in an HTL film of the desired thickness. The second HTL film is between approximately 30 and 200 nm thick.

A second ITO surface can be deposited on the second HTL surface. The devices then can be encapsulated using a glass cover slip sealed with a curable glue, or in other epoxy or plastic coatings. Cavity glass with a getter/dessicant may also be used.

### Example C

The device fabrication described below is intended as an example and does not in any way imply the limitation of the embodiments to the said fabrication process, device architecture (sequence, number of layers etc.) or materials.

The OPV/OLED devices described herein can be fabricated on indium tin oxide (ITO) surfaces deposited on glass substrates. The cleaned substrates can be coated with a first HTL. The coating process can be done on a spin coater but can easily be similarly achieved with spray coating, ink-jetting, contact printing or any other deposition method capable of resulting in an HTL film of the desired thickness. This can be followed by the spin coating of the light emitting layers, which in this example is a commercial white light emitter polymer. The white light emitter can be measured to be approximately 100 nm thick.

The coating of the polymer layers can be followed by deposition of a Ba, Ca, or LiF layer and then an approximately 80-200 nm thick Al cathode layer.

An n-type semiconducting transparent oxide layer (such as TiO₂ or ZnO) can be coated on Al cathode for better matching of electron transport states and improved electron collection.

The n-type semiconducting transparent oxide layer can be coated with an OPV active layer comprising a composition mixture comprising at least one p-type material and at least one n-type material. The OPV active layers then can be deposited by spin casting, ink jetting, doctor blading, spray casting, dip coating, vapor depositing, or any other known deposition method, on top of the HTL film. The deposition of the OPV active layers can be followed by deposition of a second Ba, Ca, or LiF layer.

The OPV active layers can be coated with a second HTL surfaces. The coating process can be done on a spin coater, or can easily be similarly achieved with spray coating, ink-jetting, contact printing or any other deposition method capable of resulting in an HTL film of the desired thickness.

A second ITO surface can be deposited on the second HTL surface. The devices then can be encapsulated using a glass cover slip sealed with a curable glue, or in other epoxy or plastic coatings. Cavity glass with a getter/dessicant may also be used.

### Example D

For transparent integrated OPV and electroluminescent device with a common cathode, such as for smart window applications, a highly transparent cathode typically has low optical absorption, and should be easily integrated into a high throughput manufacturing process.

Several transparent electrode materials exist, including, but not limited to:

1) thin metallic films coated with transparent conductive oxide such as Ca/Al, Ba/Al and Mg/Ag coated with transparent ITO or ZnO;

2) n-doped ZnO; and

3) carbon nanotubes electrode.

### Transparent Cathode

Ultra thin metallic films coated with transparent conductive oxide such as Ca/Al, Ba/Al and Mg/Ag coated with transparent conducting oxide (TCO) such as ITO or ZnO are most typically used. They can be prepared by highly controlled sputtering technique, an efficient technique that gives uniform high quality films.

Ba, Al, Mg and Ag sputtering targets are commercially available from Kurt J. Lesker.

### Example D1

A thin layer of Al, approximately 10 nm thick, is deposited by thermal evaporation or sputtered first at very low rate (approximately 0.05-0.1 A/sec) to obtain low work function first layer and to avoid damaging an organic layer. Then an ITO or ZnO layer is sputtered at high rates (approximately 1-2 A/sec) to obtain highly conductive transparent layer. And finally, a thin layer of Al, approximately 10 nm thick, is thermally deposited or sputtered to obtain low work function layer as a cathode for top photovoltaic device.

### Example D2

A thin layer of Ca, approximately 2 to 10 nm thick, is thermally evaporated at low rate (approximately 0.1 A/sec) to obtain low work function first layer. Then thin layer of Al/Ag, approximately 5 to 10 nm thick, is thermally evaporated at high rates (approximately 1-4 A/sec) or sputtered at low rates. This helps to protect an active layer from damaging by ITO sputtering and to prevent Ca oxidation during TCO sputtering. Then ITO or ZnO layer is sputtered, initially at low rates and then at high rates, to obtain highly conductive transparent layer. Following this, a thin layer of Al, approximately 10 nm thick, is thermally deposited or sputtered to obtain low work function layer as a cathode for top photovoltaic device.

### Example D3

A thin layer of Ba approximately 2 to 10 nm thick, is sputtered first at very low rate (approximately 0.01-0.1 A/sec) to obtain low work function first layer and to avoid damaging organic layer. Then a thin layer of Al/Ag, approximately 5 to 10 nm thick, is thermally evaporated at high rates (approximately 1-4 A/sec) or sputtered at low rates. This helps to protect an active layer from damaging by ITO sputtering and to prevent Ca oxidation during TCO sputtering. Then ITO or ZnO layer is sputtered initially at low rates and then at high rates to obtain highly conductive transparent layer. Following this, a thin layer of Al, approximately 10 nm thick, is thermally deposited or sputtered to obtain low work function layer as a cathode for top photovoltaic device.

### Example D4

A thin layer of Mg/Ag alloy, approximately 5 nm thick, is sputtered first at very low rate (approximately 0.01-0.1 A/sec) to obtain low work function first layer and to avoid damaging organic layer. Then ITO or ZnO layer is sputtered initially at low rates (approximately 0.01-0.1 A/sec) and then at high rates (approximately 1-5 A/sec) to obtain a highly conductive transparent layer. And then a thin layer of Al, approximately 10 nm thick, is thermally deposited or sputtered to obtain low work function layer as a cathode for top photovoltaic device.

In another embodiment, the OLED can be built-up on one transparent substrate and the OPV can be built-up on a second transparent substrate, then the two substrates can be joined or mated together and sealed by, for example, lamination. An insulating layer can be included between the two mated devices. Alternatively, the common electrode can be printed on one of the two devices and then the two devices are joined or mated together.

What is claimed is:

1. An integrated organic photovoltaic and electroluminescent device comprising:
an organic light emitting diode (OLED); and
an organic photovoltaic (OPV);
wherein the OLED and the OPV share a common substrate building layer.

2. The device of claim 1, wherein the device is a modular chip configured to be coupled to other modular chips.

3. The device of claim 1, wherein the device is configured as a lighting device.

4. The device of claim 1, wherein the OLED and the OPV share a common electrode.

5. The device of claim 1, wherein the OLED and the OPV share a common electrode, and wherein the device has a lateral dimension less than about two inches.

6. The device of claim 1, wherein the OLED and the OPV share a common cathode, and wherein the common cathode has two reflective surfaces configured to reflect light into the OLED and the OPV, respectively.

7. The device of claim 1, wherein the OLED and the OPV share a common cathode, wherein the common cathode has two reflective surfaces configured to reflect light into the OLED and the OPV, respectively, and wherein the OPV comprises a distributed Bragg reflector (DBR).

8. The device of claim 1, wherein the OLED and the OPV share a common cathode, wherein the common cathode has two reflective surfaces configured to reflect light into the OLED and the OPV, respectively, and wherein the OPV comprises a waveguide or a resonant cavity configured to reflect light multiple times within the OPV.

9. The device of claim 1, wherein the OLED and the OPV share a common cathode, wherein the common cathode has two reflective surfaces configured to reflect light into the OLED and the OPV, respectively, wherein the OPV comprises a waveguide or a resonant cavity configured to reflect light multiple times within the OPV, and wherein the waveguide or resonant cavity is optimized for wavelengths that have the highest conversion quantum efficiency for the OPV.

10. The device of claim 1, wherein the OLED and the OPV share a common anode.

11. The device of claim 1, wherein the OLED comprises a white light emitter.

12. The device of claim 1, wherein the OLED comprises a colored light emitting layer.

13. The device of claim 1, wherein
the OLED is closer to the substrate building layer than the OPV, and
the OPV is stacked on top of the OLED with respect to the substrate building layer.

14. The device of claim 1, wherein the OPV is closer to the substrate building layer than the OLED, and wherein the OLED is stacked on top of the OPV with respect to the substrate building layer.

15. The device of claim 1, further comprising a reflective surface configured to reflect light passing through the OPV back to the OPV at least once, wherein the reflective surface is also configured to reflect light generated in the OLED.

16. The device of claim 1, further comprising a cathode common to both the OPV and the OLED, wherein the cathode comprises a material selected from the group consisting of Ba, Ca, LiF, Al, Ag, and combinations thereof.

17. The device of claim 1, wherein the OPV and the OLED share a common cathode, wherein the cathode comprises Al and has two reflective surfaces configured to reflect light at least once into the OLED and the OPV, respectively.

18. The device of claim 1, further comprising a cathode that is between approximately 80 and 200 nm thick.

19. The device of claim 1 wherein the OPV comprises at least one conjugated polymer.

20. The device of claim 1, wherein the OLED comprises at least one small molecule dopant that is either fluorescent or phosphorescent.

21. The device of claim 1, wherein the OPV comprises a fullerene.

22. The device of claim 1, wherein the OPV comprises an optionally substituted polythiophene.

23. The device of claim 1, wherein the device does not comprise and is not part of a display.

24. The device of claim 1, wherein the OLED comprises a light emitting layer between approximately 30 and 150 nm thick.

25. The device of claim 1, wherein the OLED comprises a light emitting layer that is approximately 100 nm thick.

26. The device of claim 1, wherein the OPV has an active layer that is between approximately 70 and 300 nm thick.

27. The device of claim 1, wherein the OPV has an active layer that is approximately 180 nm thick.

28. The device of claim 1, wherein the OPV comprises at least one of a first HIL or a first HTL, and wherein the OLED comprises at least one of a second HIL or a second HTL.

29. The device of claim 1, wherein the OPV comprises at least one of a first HIL or a first HTL, and the OLED comprises at least one of a second HIL or a second HTL,
wherein the first HIL or HTL is between approximately 30 and 200 nm thick, and
wherein the second HIL or HTL is between approximately 30 and 200 nm thick.

30. A method for making an integrated organic photovoltaic (OPV) and electroluminescent device, said method comprising:
providing a substrate building layer optionally comprising a first transparent conductor;
providing at least one of a first HIL or a first HTL;
providing a light emitting layer;
providing a cathode;
providing an OPV active layer;
providing at least one of a second HIL or a second HTL;
providing a second transparent conductor;
providing an encapsulant;
combining the substrate building layer, the first transparent conductor, the at least one of the first HIL or the first HTL, the light emitting layer, the cathode, the OPV active layer, the second HIL and/or HTL, the second transparent conductor, and the encapsulant;
wherein the device is adapted to be a lighting device.

31. The method of claim 30, further comprising:
layering on the substrate building layer in the order:
the first HIL and/or HTL;
the OPV active layer;
the cathode;
the light emitting layer;
the second HIL and/or HTL;
the second transparent conductor; and
the encapsulant;
wherein the substrate building layer comprises the first transparent conductor.

32. The method of claim 30, further comprising:
layering on the substrate building layer in the order:
the first HIL and/or HTL;
the light emitting layer;
the cathode;
the OPV active layer;
the second HIL and/or HTL;
the second transparent conductor; and
the encapsulant;
wherein the substrate building layer comprises the first transparent conductor; and
wherein the OPV active layer comprises at least one of a fullerene, a copolymer comprising a DTP repeat unit, an aryl-substituted conjugated polymers, or an optionally substituted polythiophene.

33. An integrated organic photovoltaic and electroluminescent device comprising:
an organic light emitting diode (OLED) comprising;
a transparent electrode layer;
at least one of a first HIL or a first HTL layer comprising a regioregular polythiophene; and
a white light emitter;
an organic photovoltaic (OPV) comprising;
an OPV active layer;
at least one of a second HIL or a second HTL layer comprising a regioregular polythiophene; and
a second transparent electrode layer, and
a cathode shared by the OLED and the OPV;
wherein the OLED and the OPV share a single substrate building layer; and
wherein the device is adapted to be a lighting device.

34. The device of claim 33, wherein the OLED is stacked on top of the OPV.

35. The device of claim 33, wherein the OPV is stacked on top of the OLED.

36. The device of claim 33, wherein the OLED further comprises an interlayer comprising one of Ba, Ca, LiF, or combinations thereof.

37. The device of claim 33, wherein the OPV further comprises an interlayer comprising Ba, Ca, LiF, or combinations thereof.

38. A lighting system comprising a plurality of lighting devices, each lighting device comprising:
an organic light emitting diode (OLED); and
an organic photovoltaic (OPV);
wherein the OLED and the OPV share a common substrate building layer.

39. The lighting system of claim 38, wherein the plurality of lighting devices include devices of different colors, and wherein the lighting system is configured to produce white light in a far-field.

40. The lighting system of claim 38, wherein at least some of the plurality of lighting devices are configured to be removably mechanically and electrically coupled to each other.

41. The lighting system of claim 38, further comprising a mount, wherein at least some of the plurality of lighting devices are configured to be removably mechanically and electrically coupled to the mount.

42. An apparatus comprising:
a plurality of organic light emitting diode (OLED) regions;
a plurality of organic photovoltaic (OPV) regions; and
an insulating layer electrically separating the plurality of OLED regions and the plurality of OPV regions;
wherein at least one of the plurality of OLED regions and at least one of the plurality of OPV regions share a common substrate building layer.

43. The apparatus of claim 42, where the plurality of OPV regions are configured to be serially connected to produce a useful output voltage for charging a battery.

44. The apparatus of claim 42, where the plurality of OPV regions are configured to be serially connected to produce a peak voltage of 18-24 V.

45. The apparatus of claim 42, wherein the plurality of OLED regions are configured to be connected in parallel to permit application of a substantially equal voltage and useful current density to the plurality of OLED regions.

46. The apparatus of claim 42, wherein the plurality of OLED regions are configured to be connected in parallel to permit application of a substantially equal voltage of 4-10 V and useful current density of 20-100 mA/cm² to the plurality OLED regions.

47. The apparatus of claim 42, wherein at least some of the plurality of OLED regions have different colors, and wherein the apparatus is configured such that a far field light is substantially white.

48. An apparatus comprising:
an organic light emitting diode (OLED) region;
an organic photovoltaic (OPV) region;
a thin film battery disposed between the OLED and OPV; and
two insulating layers separating the OLED and the OPV from the thin film battery respectively;
wherein the OLED region, the OPV region, and the thin film battery share a common substrate building layer.

49. The apparatus of claim 48, further comprising a switch configured to flip the thin film battery from receiving charge from the OPV to delivering charge to the OLED.

50. An integrated photovoltaic and electroluminescent apparatus comprising:
an organic light emitting diode (OLED); and
a photovoltaic (PV) device;
wherein the OLED and the PV device share a common encapsulation, and
wherein the OLED and the PV device are built on separate transparent substrates and are joined together.

51. The apparatus of claim 50, wherein the PV device comprises an organic photovoltaic (OPV) device.

52. The apparatus of claim 50, wherein the PV device comprises at least one of a printable thin-film silicon, CIGS, CIS, or CdTe layer.

53. The apparatus of claim 50, wherein the PV device and the OLED share a common electrode.

54. The apparatus of claim 50, wherein the PV device and the OLED are separated by an insulating layer.
